(19) United States
(12) Patent Application Publication
(10) Pub. No.: US 2008/0185031 A1
(43) Pub. Date: Aug. 7, 2008

(54) FOCUSED TYPE SOLAR PLATE ASSEMBLY HAVING HEAT-DISSIPATING MODULE

(76) Inventor: Pei-Choa Wang, Pingzhen City (TW)

Correspondence Address: HDSL, 4331 STEVENS BATTLE LANE, FAIRFAX, VA, 22033, US

(21) Appl. No.: 11/671,769

(22) Filed: Feb. 6, 2007

(51) Int. Cl. H01L 31/052; H02N 6/00

(52) U.S. Cl. 136/246; 165/185

(57) ABSTRACT

A solar plate assembly includes a base, a condenser, a solar chip set and a heat-dissipating module. The condenser is connected to one side of the base. The solar chip set is provided within the base and arranged to correspond to the condenser, thereby to absorb the light refracted by the condenser and transform it into electricity as output. Further, the heat-dissipating module is connected to one side of the solar chip set, thereby to dissipate the heat generated by the solar chip set. With the above arrangement, the light intensity per unit area is increased to improve the electricity as output. Further, the heat not being transformed into electricity can be conducted to the heat-dissipating module, so that each solar chip can be continuously operated at a suitable temperature.

### BACKGROUND OF THE INVENTION

1. Field of the Invention

The present invention relates to a solar plate assembly, and in particular to a focused type solar plate assembly having a heat-dissipating module.

2. Description of Prior Art

With the development of economy, the amount of energy resources being used is rapidly increased. As a result, people rely on the petroleum to a greater extent. Especially, when the price of the petroleum continuously rises, people start to pay attention to the necessity for developing new energy resources. Among various new energy resources, the solar power energy has been considered to be the promising substitute energy in the future since it is clean without generating pollution. Further, the solar energy can be applied to various fields and is inexhaustible. Moreover, with the progress of the technology in the semiconductor industry, solar chips are gradually developed and used to solar power generation. However, there are still some problems with respect to the photoelectric transformation efficiency and the heat dissipation. Therefore, the inventor aims to improve the above problems.

The conventional solar plate assembly comprises a base, a plane mirror and a solar chip set. The planar mirror is connected to one side of the base. The solar chip set is provided in the base to correspond to a condenser, thereby to absorb the sunlight passing through the plane mirror and transform it into electricity as output. In this way, a solar plate assembly can be achieved.

However, when in use, there are still some drawbacks existing in the conventional solar plate assembly. Since the plane mirror cannot condense the light and thus the light intensity per unit area is insufficient. Therefore, a common solution is to provide a solar chip set having a larger area. Nevertheless, such solution will increase the total cost and price, and thus substantially reduces the practicability and economical effect thereof. Further, since the conventional solar plate assembly does not have a heat-dissipating module to dissipate the heat that is not transformed into electricity, the solar chip set usually operates at a higher temperature, causing the reduction in life. Therefore, there is still much room for improvement.

### SUMMARY OF THE INVENTION

The present invention is to provide a focused type solar plate assembly having a heat-dissipating module, in which a condenser is provided on one side of a solar chip so as to increase the light intensity per unit area and improve the out electricity. Further, with a heat-dissipating module, the heat not being transformed into electricity can be conducted to the heat-dissipating module, so that each solar chip can be continuously operated at a suitable temperature.

In order to achieve the above objects, the present invention provides a focused type solar plate assembly having a heat-dissipating module, which comprises a base, a condenser, a solar chip set and a heat-dissipating module. The condenser is connected to one side of the base. The solar chip set is provided within the base and arranged to correspond to the condenser, thereby to absorb the light refracted by the condenser and transform it into electricity as output. Further, the heat-dissipating module is connected to one side of the solar chip set, thereby to dissipate the heat generated by the solar chip set.

### BRIEF DESCRIPTION OF THE DRAWINGS

FIG. 1 is an exploded perspective view of the first embodiment of the present invention;

FIG. 2 is an assembled view of the first embodiment of the present invention;

FIG. 3 is an assembled cross-sectional view of the first embodiment of the present invention;

FIG. 4 is a top view showing the solar chip set of the present invention;

FIG. 5 is a top view of FIG. 4;

FIG. 6 is a cross-sectional view showing the operating state of the present invention;

FIG. 7 is an assembled cross-sectional view of the second embodiment of the present invention; and

FIG. 8 is an assembled cross-sectional view of the third embodiment of the present invention.

### DETAILED DESCRIPTION OF THE INVENTION

The detailed description and the technical contents of the present invention will be explained with reference to the accompanying drawings. However, it should be understood that the drawings are illustrative only but not to limit the present invention thereto.

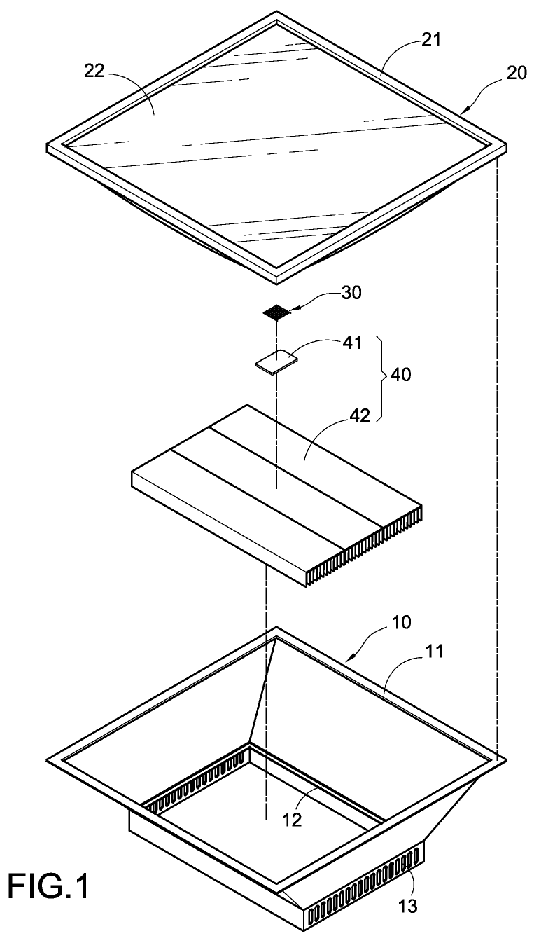

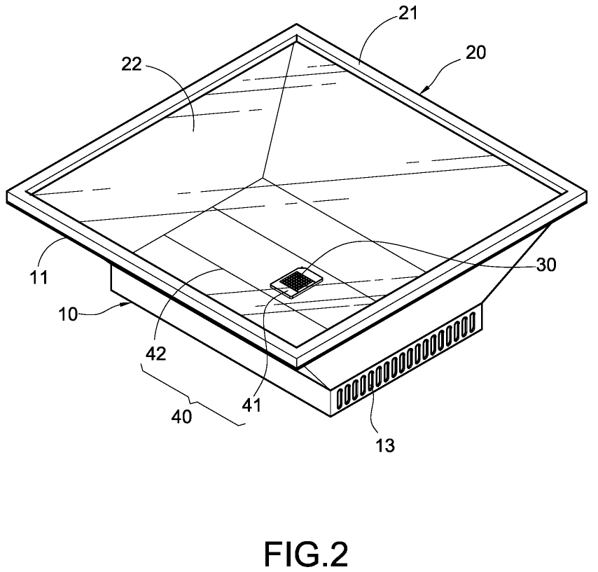

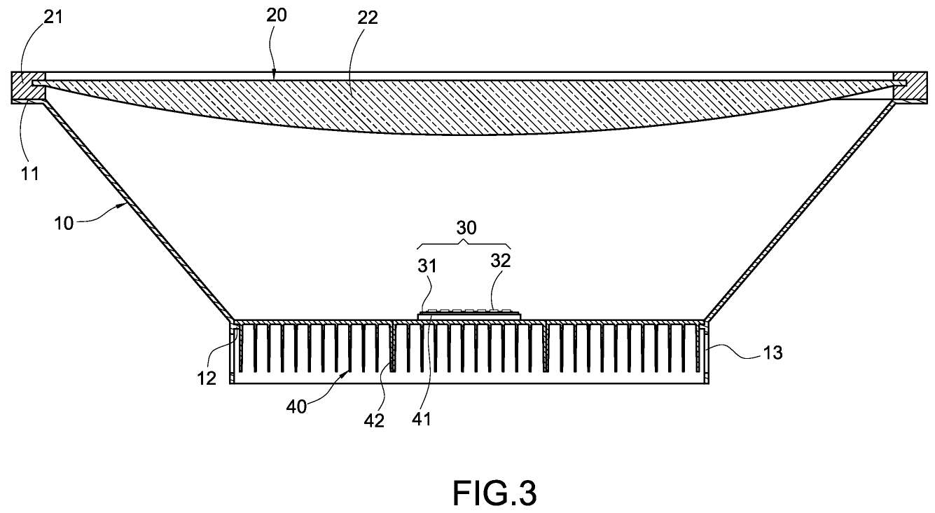

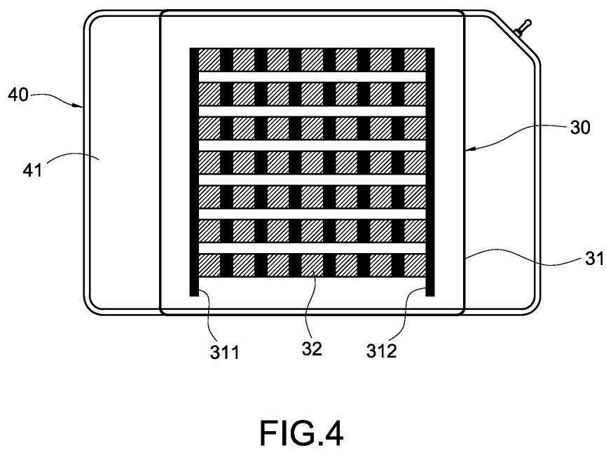

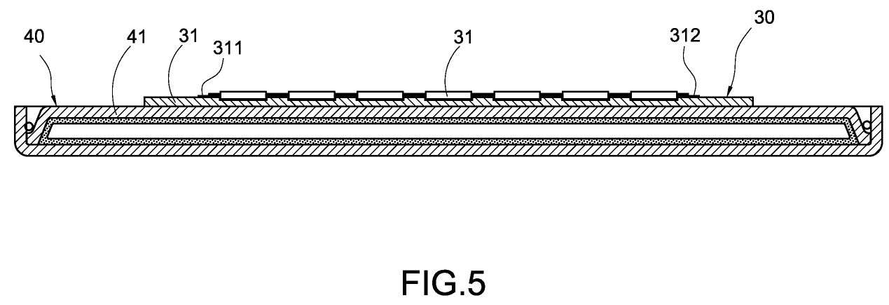

FIG. 1 is an exploded perspective view of the first embodiment of the present invention. FIG. 2 is an assembled view of the first embodiment of the present invention. FIG. 3 is an assembled cross-sectional view of the first embodiment of the present invention. FIG. 4 is a top view showing the solar chip set of the present invention. FIG. 5 is a top view of FIG. 4. The present invention provides a focused type solar plate assembly having a heat-dissipating module, which comprises a base 10, a condenser 20, a solar chip set 30 and a heat-dissipating module 40.

The base 10 is a hollow trapezoid body enclosed by a plurality of plates. A rectangular frame plate 11 extends outwardly and horizontally from the top portion of the base. A rectangular flange 12 extends inwardly from the interior of the base 10. The plates under the flange 12 are provided with a plurality of ventilating troughs 13.

The condenser 20 is connected onto the base 10, and comprises a frame 21 adhered to the frame plate 11 of the base 10 and a lens 22 inserted into the frame 21. The lens 22 can be a single convex lens whose convex surface is arranged to face the interior of the base 10.

The solar chip set 30 is disposed within the base 10 and arranged to correspond to the condenser 20. The solar chip set 30 comprises a metallic substrate 31 and a plurality of solar chips 32 connected on the substrate 31. The metallic substrate 31 may be a copper substrate. The solar chip set 32 may be constituted of PN junctions such as GaAs ` InP ` GaInP (III-V compound) whose photoelectric transformation efficiency is 28% or more. Each solar chip 32 can be fixedly connected on the metallic substrate 31 in series or parallel. The left and right sides of the substrate 31 are provided with a positive electrode 311 and a negative electrode 312 electrically connected to each solar chip 32. Each solar chip 32 is used to absorb the light refracted by the condenser 20 and to transform it into electricity as output.

The heat-dissipating module 40 is connected to one side of the solar chip set 30 for dissipate the heat generated by the solar chip set 30. The heat-dissipating module 40 of the present embodiment comprises an isothermal plate 41 adhered to the substrate 31 of the solar chip set 30 and a heat dissipator 42 adhered to another surface of the isothermal plate 41. The interior of the isothermal plate 41 is provided with capillary structure and working fluid and formed with vacuum chambers, thereby to conduct the heat with the heat transfer mechanism of vapor-liquid phase change. The heat dissipator 42 may be formed by means of combining with a plurality of heat-dissipating units. The heat-dissipating unit may be aluminum-extruded heat-dissipating pieces or a stack of heat-dissipating pieces. The outer periphery of the heat dissipator is disposed on the flange 12 of the base 10.

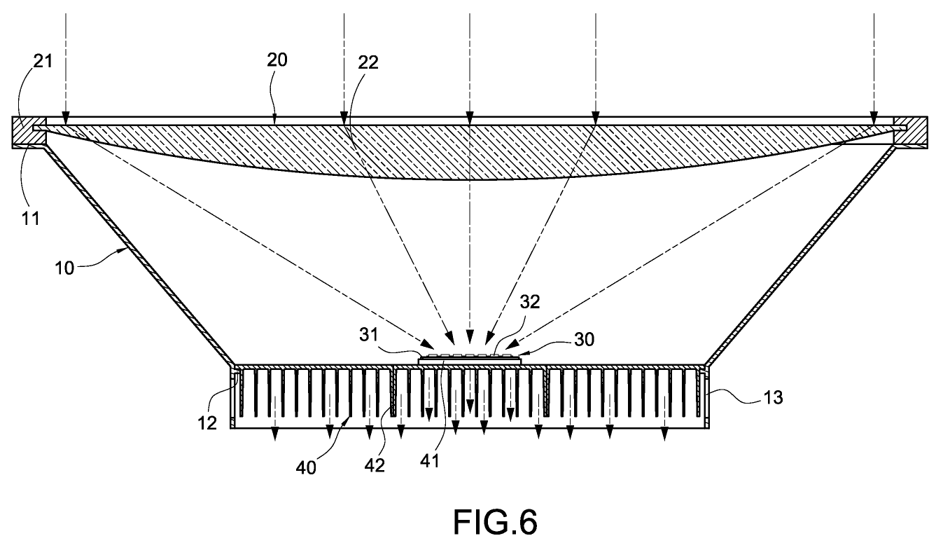

With reference to FIG. 6, it is a cross-sectional view showing the operating state of the present invention. When in use, the photons of the external light first pass through the lens 22 of the condenser 20. The photons are refracted by the lens 22 and projected on each solar chip 32, and then enter the PN junctions of the solar chip 32. If the energy of the photons is larger than the band gap of the semiconductor material, hole-electron pairs will be generated. Under the electric filed within the PN junction, the holes migrate to the P region and the electrons migrate to the N region. As a result, the P region carries positive charges and the N region carries negative charges. Therefore, a voltage or current is generated between the P region and the N region, thereby to finish the procedure of the photoelectric transformation. During the procedure, the maximum heat flux on the surface of the solar chi 32 is 49.4 Watt/cm². When the photoelectric transformation efficiency of the solar chip 32 is 28%, the heat flux may be reduced to 35.6 Watt/cm². After the heat-conducting effect of the isothermal plate 41 and the heat-dissipating effect of the heat dissipator 42 of the heat-dissipating module 40, the heat flux can be reduced to 7.51 Watt/cm².

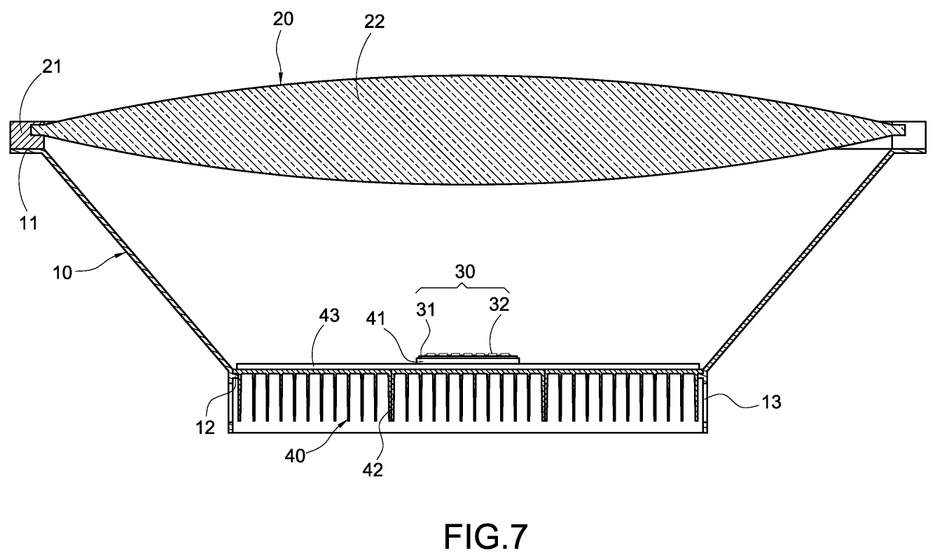

With reference to FIG. 7, it is an assembled cross-sectional view showing the second embodiment of the present invention. In the present embodiment, the condenser 20 is a double convex lens. The heat-dissipating module 40 further comprises a heat pipe 43. The middle section of the heat pipe 43 is made flat. The upper and lower end faces of the heat pipe are adhered to the bottom surface of the isothermal plate 41 and the top surface of the heat dissipator 42, respectively. Further, both ends of the heat pipe 43 extend outwardly and the bottom thereof abuts against the heat dissipator 42. In this way, the heat can be rapidly dissipated to a long distance and dissipated to the outside via the heat dissipator 42.

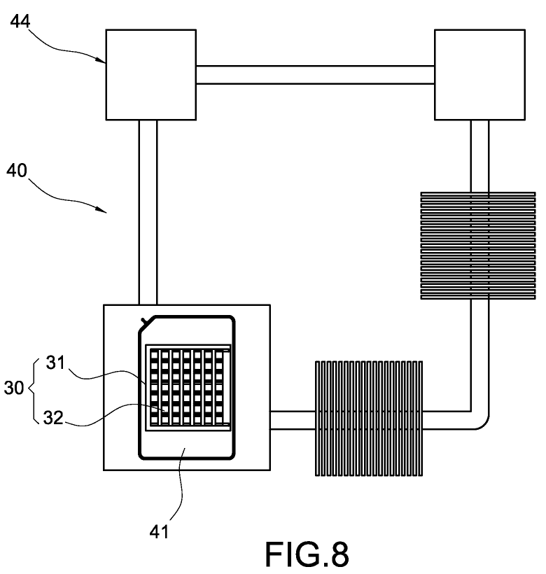

With reference to FIG. 8, it is an assembled cross-sectional view of the third embodiment of the present invention. In the present embodiment, the heat-dissipating module 40 comprises an isothermal plate 41 and a water-cooling means 44. The water-cooling means 44 comprises a water-cooling head, a water tank, a pump and a water-cooling assembly. The top surface of the water-cooling head is adhered to the bottom surface of the isothermal plate 41. The water-cooling head is in fluid communication with the water tank by a water conduit. The outside of the water conduit is provided with the water-cooling assembly constituted of a plurality of fins. The water tank is in fluid communication with the pump and the water-cooling head by water conduits. With the above arrangement, it can generate the same effect as that of the heat-dissipating module.

According to the above, the present invention indeed has industrial applicability, novelty and inventive steps. Further, the present invention has not been published or put to public use prior to applying for a patent, and thus really conforms to the requirements for a utility model patent.

Although the present invention has been described with reference to the foregoing preferred embodiments, it will be understood that the invention is not limited to the details thereof. Various equivalent variations and modifications can still be occurred to those skilled in this art in view of the teachings of the present invention. Thus, all such variations and equivalent modifications are also embraced within the scope of the invention as defined in the appended claims.

What is claimed is:

1. A focused type solar plate assembly having a heat-dissipating module, comprising:
a base;
a condenser connected to one side of the base;
a solar chip set provided within the base and arranged to correspond to the condenser, thereby to absorb the light refracted by the condenser and transform it into electricity as output; and
a heat-dissipating module connected to one side of the solar chip set, thereby to dissipate the heat generated by the solar chip set.

2. The focused type solar plate assembly having a heat-dissipating module according to claim 1, wherein the base is a hollow trapezoid body, a frame plate extends from the top portion of the base, the condenser comprises a frame adhered to the frame plate and a lens inserted into the frame.

3. The focused type solar plate assembly having a heat-dissipating module according to claim 2, wherein the lens is a single convex lens.

4. The focused type solar plate assembly having a heat-dissipating module according to claim 2, wherein the lens is a double convex lens.

5. The focused type solar plate assembly having a heat-dissipating module according to claim 2, wherein a flange extends from the interior of the base, the heat-dissipating module comprises an isothermal plate adhered to the solar chip set and a heat dissipator adhered to another surface of the isothermal plate, and the outer periphery of the heat dissipator is disposed on the flange.

6. The focused type solar plate assembly having a heat-dissipating module according to claim 5, wherein the base below the flange is provided with a plurality of ventilating troughs to correspond to one another.

7. The focused type solar plate assembly having a heat-dissipating module according to claim 5, wherein the heat-dissipating module further comprises a heat pipe, the middle section of the heat pipe is adhered to the bottom surface of the isothermal plate, and both ends of the heat pipe are adhered to the heat dissipator.

8. The focused type solar plate assembly having a heat-dissipating module according to claim 1, wherein the solar chip set comprises a metallic substrate adhered to the heat-dissipating module and a plurality of solar chips connected on the substrate.

9. The focused type solar plate assembly having a heat-dissipating module according to claim 8, wherein the metallic substrate is a copper substrate.

10. The focused type solar plate assembly having a heat-dissipating module according to claim 8, wherein both sides of the substrate are provided with a positive and a negative electrodes electrically connected to each solar chip, respectively.

11. The focused type solar plate assembly having a heat-dissipating module according to claim 8, wherein each solar chip is connected in series.

12. The focused type solar plate assembly having a heat-dissipating module according to claim 8, wherein each solar chip is connected in parallel.

13. The focused type solar plate assembly having a heat-dissipating module according to claim 1, wherein the solar chip is constituted of any of GaAs, InP or InGaP.

14. The focused type solar plate assembly having a heat-dissipating module according to claim 1, wherein the heat-dissipating module comprises an isothermal plate adhered to the solar chip set and a water-cooling means partially adhered to the isothermal plate.
